(19) United States
(12) Patent Application Publication
(10) Pub. No.: US 2004/0187790 A1
(43) Pub. Date: Sep. 30, 2004

(54) Substrate holder

(75) Inventors: Stefan Bader, Eilsbrunn (DE); Matthias Peter, Regensburg (DE); Alexander Walter, Laaber (DE); Volker Haerle, Laaber (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 10/748,305

(22) Filed: Dec. 30, 2003

(30) Foreign Application Priority Data
Dec. 30, 2002 (DE) 102 61 362.1

(51) Int. Cl. C23C 16/00

(52) U.S. Cl. 118/728

(57) ABSTRACT

In order to achieve an as uniform as possible temperature over the entire surface of the substrate (2) during a temperature step and, in particular, during an epitaxy method, temperature equalization structures are incorporated in a substrate holder (1), on which the substrate (2) is located. A uniform temperature distribution on the substrate surface during the deposition of a semiconductor material reduces the emission wavelength gradient of the deposited semiconductor material. The temperature equalization structures produce specific temperature inhomogeneities in the substrate holder (1), and these smooth out the temperature profile of the substrate (2). For example, a groove (4) with a cooling effect and a support step (5) which produces a gap (8) between the substrate (2) and the substrate holder (1) are integrated in the edge area of the substrate holder (1).

### CROSS REFERENCE TO RELATED APPLICATIONS

This patent application claims the priority of the German Patent Application 102 61 362.1-43, the disclosure content of which is hereby incorporated by reference.

1. Field of the Invention

The invention relates to a substrate holder, in particular for a facility for epitaxial deposition of semiconductor material on a substrate, having a substrate supporting face and a holder rear face, which faces away from this supporting face, and a facility for the deposition of a semiconductor material.

2. Background of the Invention

Substrate holders such as these are used, for example, in metal-organic vapor phase epitaxy (MOVPE). A substrate holder which is composed of graphite typically has a silicon carbide coating for the deposition of nitride compounds. The substrate then rests on the silicon carbide coating.

This type of substrate holder has the disadvantage that temperature inhomogeneities are produced on the surface of the substrate during the deposition process at increased temperatures. The semiconductor material is deposited on this substrate surface. The emission wavelength of some radiation-emitting semiconductor materials is highly dependent on the deposition temperature, which corresponds to the surface temperature of the substrate. For example, the emission wavelength of gallium nitride-based materials (in particular of gallium indium nitride) is highly temperature-dependent. In this case, the deposition process typically takes place at temperatures between 700° C. and 800° C. In order to ensure that the semiconductor material which is deposited has as narrow an emission wavelength distribution as possible (and, ultimately, little variation in the emission wavelength of the completed components), it is necessary to achieve a temperature distribution which is as homogeneous as possible over the substrate surface. For example, in order to deposit gallium indium nitride, it is desirable to have a temperature distribution with temperature differences of less than 5° C. The deposition of aluminum indium gallium nitride is particularly temperature-sensitive, during which a temperature difference of more than 1° C. can lead to major variations in the emission wavelength of the aluminum indium gallium nitride components.

In addition to the temperature distribution on the substrate holder surface, the material of the substrate and its planarity, thermal conductivity and mechanical stress play a critical role in the surface temperature on the substrate. Epitaxy on sapphire substrates is significantly different from epitaxy on silicon carbide substrates, because widely differing temperature profiles occur on the substrate surface, so that a wavelength distribution of different width thus also occurs in the deposited semiconductor material. The temperature distribution on the surface of the silicon carbide substrates thus differs considerably from that on sapphire substrates. This leads, inter alia, to a very much greater wavelength gradient in the deposited semiconductor material.

The great majority of semiconductor manufacturers use sapphire as a growth substrate for the aluminum indium gallium nitride material system. For this reason, the substrate holders used by the conventional facility manufacturers are designed for sapphire substrates, in which the problem mentioned above does not occur. Thus, until now, no measures have been taken to specifically achieve homogenization of the substrate surface temperature and hence also of the emission wavelength of the deposited semiconductor material.

### SUMMARY OF THE INVENTION

One object of the present invention is to develop a substrate holder and a facility of the type mentioned initially which allow the deposition of semiconductor material with an emission wavelength distribution which is as narrow as possible.

A substrate holder, in particular for a facility for epitaxial deposition of semiconductor material on a substrate, includes a substrate supporting face and a holder rear face, which faces away from this supporting face. The substrate holder has a temperature equalization structure which results in a defined temperature profile over the entire substrate surface of a substrate which is located on or in the vicinity of the substrate holder, during a process which includes heating or cooling.

The invention involves the use of a substrate holder with a temperature equalization structure which produces a defined temperature profile or in particular a temperature which is as uniform as possible over the entire substrate surface of a substrate which is located on the substrate holder or a facility for the epitaxial deposition of a semiconductor material, which includes a substrate holder such as this.

A temperature equalization structure of the type mentioned above produces specific temperature inhomogeneities on the substrate holder surface, which in turn smooth out the temperature distribution on the substrate surface. A temperature equalization structure having a corresponding cooling effect is incorporated in the substrate holder at those points on the substrate which are hotter. Conversely, a temperature equalization structure having greater heat transmission is installed in the substrate holder at those points on the substrate which are cooler. This results in compensation for the temperature inhomogeneities on the substrate surface.

The substrate can be heated by means of convection, heat radiation and/or thermal conduction. Resistance or induction heating is typically used. Resistance heating is used to heat the substrate holder directly, for example by means of a heating wire (that is to say the heating body). For induction heating, an electrically conductive substrate holder is heated by using induction to produce a current in the substrate holder. The substrate holder is in this case at the same time the heating body. In both cases, in the case of a substrate which makes direct contact, the majority of the heat is transmitted from the substrate holder to the substrate by means of thermal conduction. In order to achieve a as homogeneous as possible temperature profile with a configuration such as this, it is necessary to ensure that there is good contact between the substrate and the substrate holder, as far as possible over the entire lower surface of the substrate.

A further advantageous embodiment provides for the substrate to rest on the substrate holder so as to produce a gap between the substrate and the substrate holder. The gap must in this case be chosen to be sufficiently large that the majority of the heat transmission takes place by heat radiation, and that the thermal conduction can largely be ignored. The substrate is thus advantageously heated mainly by means of heat radiation and convection. In this case, for uniform heating, it is necessary for the distance between the substrate holder and the substrate to be as constant as possible over the entire substrate. Since the substrate can bend during the heating process, the substrate can thus make direct contact with the substrate holder, with a hotter point being formed by direct thermal conduction on the substrate surface. In order to avoid such a contact, the gap between the substrate and the substrate holder can be chosen such that the gap is greater than the expected bending of the substrate. The gap can advantageously be produced by means of a substrate support structure (for example a support ring).

The substrate is normally located in a depression in the substrate holder. The edge area of the substrate is therefore heated both from underneath and from the side and is consequently hotter than the center of the substrate. In order to compensate for this overheating of the edge, a circumferential annular groove can preferably be integrated on the substrate supporting face or on the rear face of the substrate holder. If the substrate holder and the heat source are separated by a gap, it is preferable to have a groove on the rear face of the substrate holder. A groove on the holder rear face is used to ensure that the substrate holder directly above the groove and hence also that area of the substrate holder which surrounds the groove is cooler than the rest of the substrate holder. This cooler area is produced in the substrate holder because the majority of the heat transmission from the heat source to the substrate supporting face of the substrate holder takes place by thermal conduction, which is dependent on the distance from the heat source, and because the distance between the substrate holder and the heat source is greater in the groove than at other points. The gap is in this case preferably chosen to be sufficiently small that the majority of the heat transmission takes place by thermal conduction, and that heat radiation can be ignored. The substrate may be placed on the substrate holder such that it rests directly on the substrate holder or, for example, rests on a support ring above the substrate holder. In addition, the substrate (with or without a gap between the substrate and the substrate holder) can completely or partially cover the area above the groove, or may be arranged next to this area.

In contrast, if the heat source makes direct contact with the substrate holder, or the substrate holder is itself the heat source, it is preferable to use a circumferential annular groove on the substrate supporting face of the substrate holder. With a configuration such as this, the substrate can be placed at least partially over the groove. The groove is advantageously completely covered, in order to avoid the deposition of semiconductor material on the lower face of the substrate. Semiconductor material on the lower face of the substrate results in problems during the further processing of the semiconductor component. The substrate may also cover the area of the substrate holder between the edge and the groove. The arrangements which have already been mentioned are also possible in conjunction with a gap between the substrate and the substrate holder.

In a further preferred embodiment, the substrate supporting face of the substrate holder is equipped with two or more grooves, the distance between which and/or whose depth/s are/is matched to the temperature profile of the substrate. This generally means that the distance between grooves in areas where the temperatures are relatively high is less than in areas where the temperatures are relatively low. Similarly, the depth of the grooves can be set such that the areas where the temperatures are relatively high have deeper grooves than the areas where the temperatures are relatively low.

The substrate holder may advantageously have texturing on the substrate supporting face or on the holder rear face, comprising a three-dimensional pattern. One such pattern, is by way of example a hatch pattern which is formed by fine parallel trenches. A crossed-hatch pattern and other patterns which may also, for example, comprise pits, are also suitable. In areas where the temperature is relatively high, the pattern is organized to be denser than in areas where the temperature is relatively low. In this case, a denser pattern corresponds to a pattern in which the pattern elements (for example the trenches and/or pits) are arranged closer to one another, and may also be smaller.

The substrate supporting face of the substrate holder is advantageously provided with two or more circumferential steps, thus forming a continuous step system (that is to say a continuously stepped relief). This configuration is mainly preferable in conjunction with the substrate being heated by thermal conduction, that is to say when there is a gap that is sufficiently small between the substrate and the substrate holder. The depth of the steps is matched to the temperature profile of the substrate, so that the deeper steps are located underneath those areas of the substrate in which the temperatures are relatively high, and the smaller steps are arranged where the temperatures are relatively low.

A further embodiment has a recess on the substrate supporting face of the substrate holder, in or above which the substrate is at least partially arranged. This configuration is particularly advantageous in conjunction with a substrate support structure, because the lower face of the deeper placed substrate is less subject to the deposition of the semiconductor material.

The surface roughness or evenness of the substrate holder is preferably in the same order of magnitude as that of the substrates which are used.

The substrate holder is preferably composed of a silicon carbide solid material, instead of the conventional graphite coated with silicon carbide. This leads to the thermal conductivity of the substrate holder being better and thus to more homogeneous temperatures, a longer life of the substrate holder owing to the lack of thermal stresses between the coating and the graphite, and easier (chemical and mechanical) cleaning of the substrate holder. Substrate holders which are composed of solid silicon carbide material can be subsequently further processed and/or contoured (for example by means of a material processing laser).

Combinations of two or more of the embodiments described above are also feasible.

### BRIEF DESCRIPTION OF THE DRAWINGS

FIG. 1a and 1b respectively show a schematic cross sectional illustration and a schematic plan view of a first exemplary embodiment of a substrate holder according to the invention,

FIGS. 2a to 2d show schematic cross sectional illustrations of different variations of a first exemplary embodiment of a substrate holder according to the invention,

FIG. 3 shows a schematic plan view of a second exemplary embodiment of a substrate holder according to the invention,

FIGS. 4a to 4e show schematic cross sectional illustrations of different variations of a second exemplary embodiment of a substrate holder according to the invention,

FIG. 5 shows a schematic plan view of a third exemplary embodiment of a substrate holder according to the invention,

FIGS. 6a, 6b and 6c each show a schematic cross sectional illustration and a schematic plan view of a fourth exemplary embodiment of a substrate holder according to the invention,

FIGS. 7a and 7b respectively show a schematic cross sectional illustration and a schematic plan view of a fifth exemplary embodiment of a substrate holder according to the invention,

FIG. 8 shows a schematic cross sectional illustration of a sixth exemplary embodiment of a substrate holder according to the invention, and

FIG. 9 shows a schematic plan view of a seventh exemplary embodiment of a substrate holder according to the invention.

### DETAILED DESCRIPTION OF THE DRAWINGS

Identical elements or elements with the same effect are provided with the same reference symbols in the figures. The figures are not shown to scale, in order to make it easier to understand them.

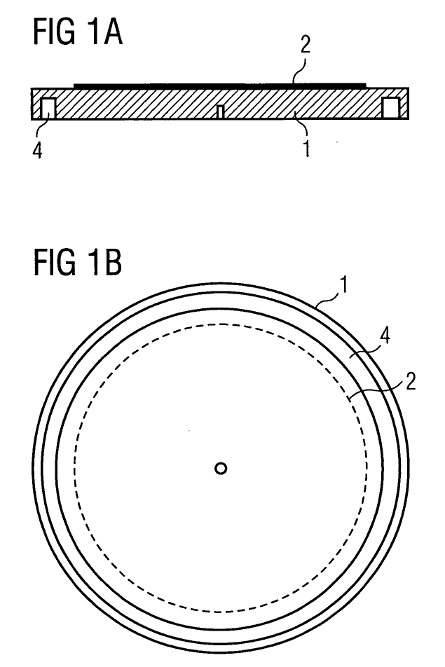

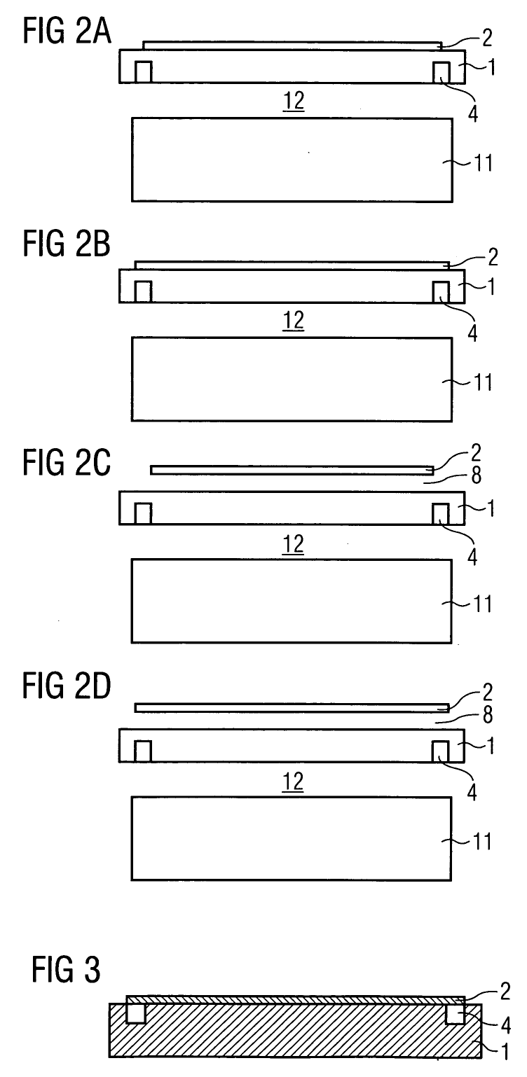

The substrate holder 1 which is illustrated in FIG. 1a and 1b has a groove 4 on the lower face, circulating at the edge of the substrate holder 1. By way of example, the substrate holder 1 is composed of solid silicon carbide material and has a thickness of about 7 mm. The groove 4 may also be arranged on the upper face of the substrate holder. The groove 4 has, for example, a depth of 3.5 mm and a width of 2.5 mm. However, the width may also be up to 80% of the radius of the substrate holder 1. It has for example, a quadrilateral shape in cross section. The size and the cross section of the groove 4 can be varied depending on the temperature profile, in order to achieve a largely uniform temperature distribution over the substrate holder 1. A substrate 2, to which the semiconductor material is applied, rests on the substrate holder 1. A heat source 11 is arranged underneath the substrate holder 1, in order to heat the substrate holder 1 (this is not shown in FIGS. 1a and 1b, but is shown in FIGS. 2a to 2d).

The heat source 11 is preferably separated by a gap 12 from the substrate holder 1, because the substrate holder 1 is then heated by radiation. Accordingly, the part of the substrate holder 1 above the groove 4 is heated to a lesser extent than the rest of the substrate holder 1, because it is further away from the radiation source (that is to say the heat source 11). The groove 4 runs all the way round the edge of the substrate holder 1 (see FIG. 1b). In this exemplary embodiment, the substrate 2 is placed directly on the substrate holder 1 adjacent to the area which is immediately above the groove 4.

FIGS. 2a to 2d show further possible relative arrangements of the substrate 2, of the substrate holder 1 and of the groove 4. FIGS. 2a and 2b show substrates which are placed directly on the substrate holder 1, on the one hand partially covering the area above the groove 4 (see FIG. 2a) and on the other hand covering the areas above the groove 4 and between the groove 4 and the edge (see FIG. 2b). FIGS. 2c and 2d show substrates 2 which are separated from the substrate holder 1 by a gap 8. This gap 8 is produced, for example, by means of a support structure (which is not illustrated). In FIG. 2c, the area above the groove is not covered by the substrate 2 and, in FIG. 2d, this area and part of the area between the groove 4 and the edge are covered. Other further positions of the substrate 2 are also feasible.

In a second exemplary embodiment, the groove 4 which is shown in FIGS. 1 and 2 is arranged on the upper face of the substrate holder 1 at the edge (see FIG. 3). An arrangement such as this is more suitable for heating by thermal conduction (for example contact heating or induction heating), because the normally hotter edge area of the substrate 2 can be arranged above the groove 4. The edge area of the substrate 2 is then not heated as much as those parts of the substrate 2 which make direct contact with the substrate holder 1. For example, the substrate 2 which is shown in FIG. 3 completely covers the groove 4 thus forming a closed gap which, for example, is filled with gas, between the lower face of the substrate 2 and the substrate holder 1.

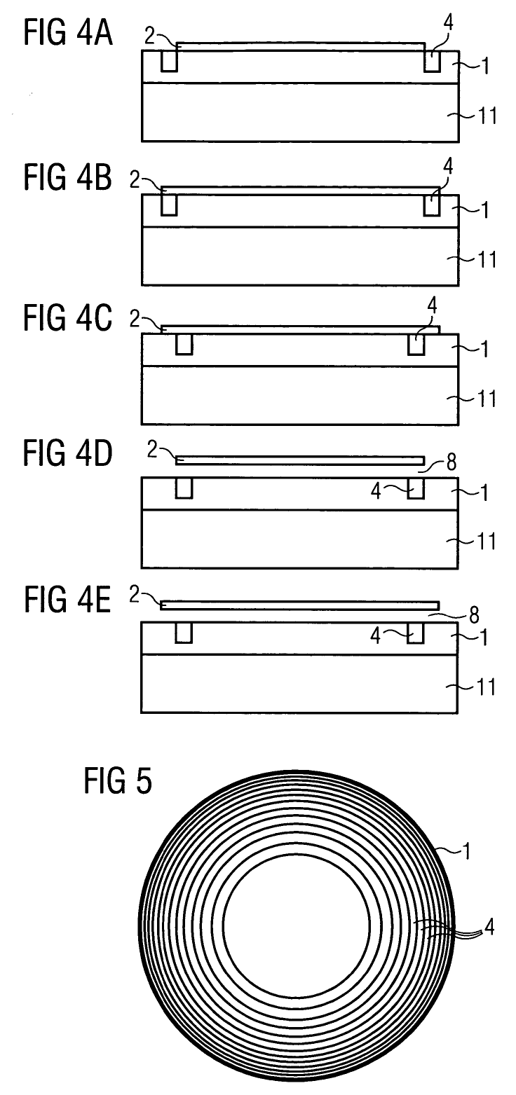

The substrate 2 may also partially cover the groove 4, or may at least partially cover the substrate holder surface between the groove 4 and the edge (see FIGS. 4a to 4c). The groove 4 is preferably completely covered, so that no semiconductor material is deposited on the lower face of the substrate 2 during the deposition of the semiconductor material. The substrate 2 may also be separated from the substrate holder 1 by a gap 8 (see FIGS. 4d and 4e). The gap 8 is produced by means of a support structure (which is not illustrated). If the entire edge area of the substrate 2 rests on a circumferential support structure the lower face of the substrate 2 is protected against deposition of the semiconductor material, because the gap 8 is, as a consequence of this closed.

FIG. 5 shows a third exemplary embodiment. The substrate holder 1 is contoured on the upper face or lower face, wherein the contouring is composed of a number of small grooves 4. The grooves 4 in this case have, for example, a width of 25 μm and a depth of 100 μm. By way of example, they are arranged in an annular shape and concentrically, such that the distance between the grooves 4 in the edge area of the substrate holder 1 is less than that in the central area of the substrate holder 1, because the edge area temperatures are normally higher than those in the central area. The precise distance between the grooves 4 (that is to say the density of the grooves) is matched to the temperature profile of the substrate holder 1 and/or of the substrate 2. The greater the extent to which the temperature of the substrate 2 differs from the average temperature of the substrate 2, the denser is the arrangement of the grooves 4. In order to produce an as stable as possible temperature profile on the substrate 2, it is necessary that the contouring be very fine . The substrate holder 1 is composed, for example, of a solid silicon carbide material. The substrate holder 1 may also be composed of graphite with a silicon carbide coating on the upper face, however the silicon carbide coating is then preferably thicker than the depth of the grooves 4. It is also feasible for the contouring to be arranged on the lower face of the substrate holder.

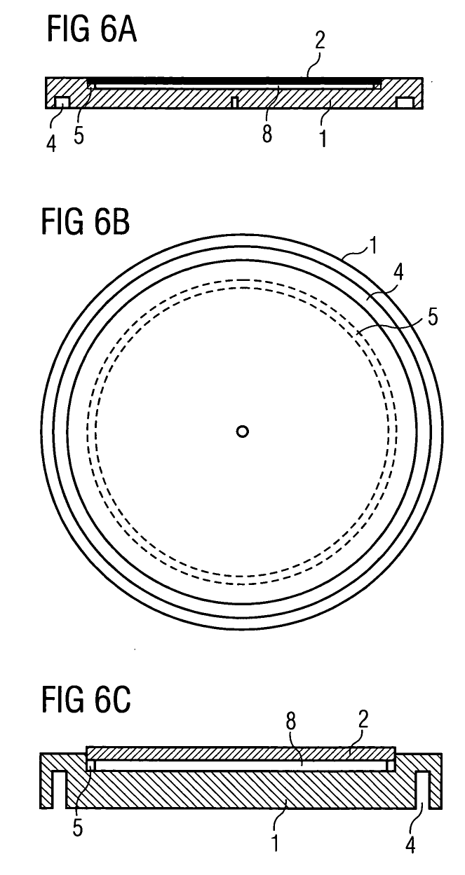

The substrate holder 1 which is illustrated in FIGS. 6a and 6b has a support structure, for example an annular support step 5, at the edge on the upper face. This annular support step 5 is arranged in a recess in the support surface of the substrate holder. The edge support results in a defined gap 8 between the substrate holder 1 and the substrate 2. This gap 8 must be at least sufficiently large for the heat to be constantly transmitted by means of radiative heat, despite substrate bending (before and during the epitaxy).

By way of example, the support step has a width of 1 mm and projects 0.5 mm above the base of the recess, that is to say in this case the gap 8 has a thickness of 0.5 mm. The recess is preferably deeper than the support step (that is to say deeper than 0.5 mm in this example) so that at least the lower face of the substrate 2, which rests on the support step, is located deeper than the edge area of the substrate holder 1 (see FIG. 6a).

By way of example, FIG. 6c shows a substrate holder 1 with a support step in a recess, in which, although the substrate 2 is located deeper than the edge area of the substrate holder 1, the substrate surface nevertheless projects from the edge area of the substrate holder 1. The recess is at least as large as the surface of the substrate 2, so that the recess can accommodate this surface. A groove 4, as is illustrated in FIG. 1, is additionally incorporated in this exemplary embodiment, but need not be provided. Other support structures are also feasible.

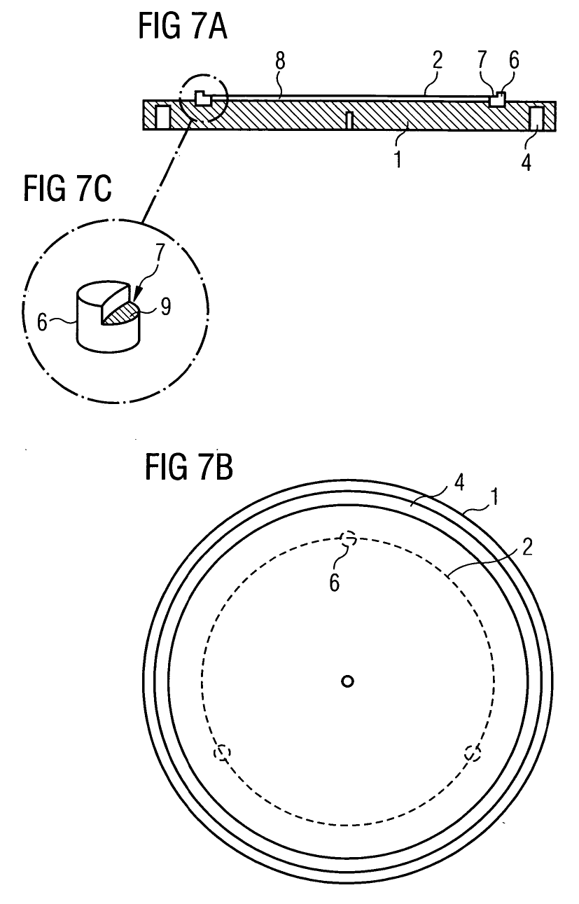

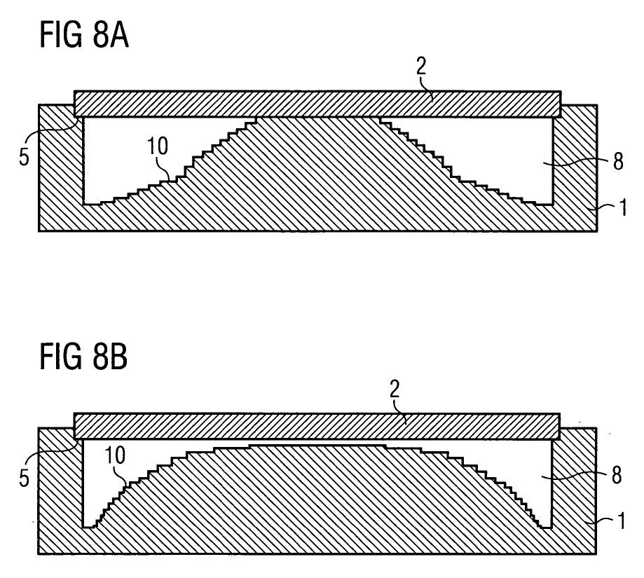

FIGS. 7a, 7b and 7c show a variant of the above exemplary embodiment. In this case, the platforms 6 are used as stops with an incision 7 in order to hold the substrate 2, wherein the incision 7 has at least one substrate support surface 9 that is located parallel to the substrate holder surface. The substrate 2 is then located on the substrate support surfaces 9 in the incisions 7 of the platforms 6, so that a gap 8 is produced between the substrate 2 and the substrate holder 1. The incisions 7 may be matched to the shape of the substrate edge. An incision 7 may have a width of about 1.5 mm (that is to say half the diameter of the platform) and a depth of approximately 1 mm. The platforms 6 project approximately 3 mm above the substrate holder surface. Since, in this case, the heat is mainly transmitted from the substrate holder 1 to the substrate 2 by heat radiation, the gap 8 is preferably bigger than the expected bending of the substrate 2 due to thermal stresses.

FIGS. 8a and 8b show two variants of a further exemplary embodiment, in which the substrate supporting face of the substrate holder has two or more circulating concentric steps 10. In FIG. 8a, the substrate 2 rests on a support step 5 in the edge area of the substrate holder 1, and on the substrate holder surface in the central area. The gap 8 in the area in which no contact is made between the substrate holder 1 and the substrate 2 is thus annular. If the gap is sufficiently small, the heat is in this case transmitted mainly by means of thermal conduction via the gap and thermal conduction by contact in the central area of the substrate 2, and at the support step. The substrate 2 may, however, just rest on the support step 5 without the substrate 2 coming into contact with the central substrate holder surface (see FIG. 8b). In a situation such as this, a circular gap 8 is formed, with a different, continuously graduated depth.

The depth of the individual steps 10 is governed by the temperature profile of the substrate holder 1, in order to achieve a temperature profile which is very largely uniform. Since the edge of the substrate holder 1 is normally hotter than the central area of the substrate holder 1, the distance between the substrate 2 and the substrate holder 1 is greater, and the heat transmission is thus less. In contrast to this, the temperature in the central area of the substrate holder is normally lower and, for this reason, the central area is arranged to be in support with or relatively close to the substrate holder 1 .

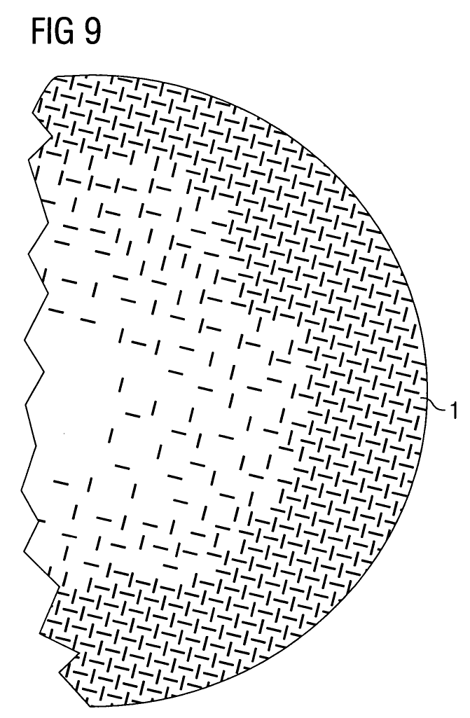

FIG. 9 shows a section of a further exemplary embodiment, in which the substrate support surface of the substrate holder 1 is textured. By way of example, the texturing in this case comprises trenches, whose pattern forms a hatch pattern. The trenches are at different distances from one another. In the areas of the substrate 2 in which the temperatures are relatively high, the distance between the trenches is less in the corresponding area of the substrate holder 1 (that is to say the pattern is denser) than in areas in which the temperatures are relatively low. Since the edge area of the substrate 1 is normally at relatively high temperatures, the substrate holder 1 illustrated in FIG. 9 is provided with a denser pattern than that in the central area. The depth of the trenches may also be matched to the temperature profile of the substrate 2, by deeper trenches being located in areas of the substrate holder 1 which are opposite hotter areas of the substrate 2. Conversely, flatter trenches or no trenches are arranged in areas which are located opposite cooler areas of the substrate 2. The texturing may also comprise pits or other patterns.

The scope of protection of the invention is not restricted by the description of the invention on the basis of the exemplary embodiments. In fact, the invention covers any novel feature as well as any combination of features which, in particular, includes any combination of features in the patent claims, even if this combination is not explicitly stated in the patent claims.

We claim:

1. A substrate holder (1), in particular for a facility for epitaxial deposition of semiconductor material (3) on a substrate (2), having a substrate supporting face and a holder rear face, which faces away from this supporting face,
wherein
the substrate holder (1) has a temperature equalization structure which results in a defined temperature profile over the entire substrate surface of a substrate (2) which is located on or in the vicinity of the substrate holder (1), during a process which includes heating or cooling.

2. The substrate holder as claimed in claim 1, in which the temperature equalization structure results in an as uniform as possible temperature over the entire substrate surface.

3. The substrate holder as claimed in claim 1, in which the temperature equalization structure is one or more three-dimensional structures in the substrate supporting face and/or in the holder rear face.

4. The substrate holder as claimed in claim 3, in which the three-dimensional structures are formed by at least one groove (4) which runs in the vicinity of the edge.

5. The substrate holder as claimed in claim 4, in which the width of the groove or grooves (4) is at most 80% of the radius of the substrate holder, and the depth of the groove or grooves (4) is less than the thickness of the substrate holder (1) or of a coating which is located on the substrate supporting face.

6. The substrate holder as claimed in claim 4, in which the groove or grooves (4) is or are arranged in an annular shape and concentrically.

7. The substrate holder as claimed in claim 4, in which the distance between the grooves (4) in areas in which relatively high temperatures occur during or after the mentioned process, in particular during the growth of semiconductor material, is less than in the areas in which temperatures which are lower than these occur.

8. The substrate holder as claimed in claim 4, in which the depth of the grooves (4) is greater in areas in which relatively high temperatures occur during the growth of the semiconductor material than in areas in which temperatures which are lower than these occur.

9. The substrate holder as claimed in claim 4, in which the groove or grooves (4) has or have a quadrilateral, circular or oval cross section, or a cross section with a segment of one of these shapes.

10. The substrate holder as claimed in claim 1, in which the temperature equalization structure comprises texturing.

11. The substrate holder as claimed in claim 10, in which the texturing includes two or more trenches and/or pits, the distance between which is matched to the temperature profile of the substrate holder (1), in such a way that the distance between trenches and/or pits in areas in which relatively high temperatures occur during the growth of the semiconductor material is less than in areas in which temperatures which are lower than these occur.

12. The substrate holder as claimed in claim 10, in which the texturing includes two or more trenches and/or pits, whose depth is matched to the temperature profile of the substrate holder (1) such that the trenches and/or pits are deeper in areas in which relatively high temperatures occur during the growth of semiconductor material than in areas in which temperatures which are lower than these occur.

13. The substrate holder as claimed in claim 10, in which the texturing includes
trenches wherein at least some of these cross one another,
trenches wherein at least some of these are arranged parallel to one another,
trenches where at least some of these are curved,
pits which are in the form of dots, circles or cuboids,
pits which have a combination of dotted, circular and/or cuboid shapes, or
trenches and/or pits which have a combination of at least two of the shapes mentioned above.

14. The substrate holder as claimed in claim 1, in which the temperature equalization structure comprises two or more circulating steps of different depths.

15. The substrate holder as claimed in claim 14, in which the steps are arranged concentrically and centrally.

16. The substrate holder as claimed in claim 14, in which the surface which is provided with steps has a continuously stepped relief.

17. The substrate holder as claimed in claim 14, in which the depth of the steps is matched to the temperature profile of the substrate holder (1), such that the depth of the steps is greater in areas in which relatively high temperatures occur during the growth of semiconductor material than in areas in which temperatures which are lower than these occur.

18. The substrate holder as claimed in claim 1, in which the substrate supporting face has a substrate support structure, by means of which, when the substrate is supported, a gap (8) is formed between the substrate (2) and the substrate holder.

19. The substrate holder as claimed in claim 18, in which the substrate support structure is designed such that essentially only the edge or those areas of the substrate (2) which are on the edge are supported, and the substrate (2) essentially makes no contact with the substrate holder (1) anywhere else.

20. The substrate holder as claimed in claim 18, in which the substrate support structure has a step which surrounds the substrate.

21. The substrate holder as claimed in claim 18, in which the substrate support structure comprises at least one substrate stop for holding the substrate (2), wherein the substrate stop has a substrate support surface (9) above the substrate holder surface.

22. The substrate holder as claimed in claim 21, in which the substrate stop is formed by means of a hemisphere or a platform (6) with an incision (7), which has at least one substrate support surface (9) parallel to and above the substrate holder surface.

23. The substrate holder as claimed in claim 1, in which a recess is provided on the substrate supporting face of the substrate holder (1) and is at least sufficiently large that the substrate (2) can at least partially be arranged in the recess, parallel to the support surface of the substrate holder (1).

24. The substrate holder as claimed in claim 1, in which the surface of the substrate holder has a roughness of less than 10 μm.

25. The substrate holder as claimed in claim 1, in which the substrate holder (1) has a ground and/or polished surface.

26. A facility for epitaxial deposition of a semiconductor material (3) on a substrate (2) having at least one reactor, one gas mixing system and one exhaust gas system, with the reactor having at least one substrate holder (1), a mount for the substrate holder (1) and a means for heating,
wherein
the substrate holder (1) is designed as claimed in claim 1.
